(19) United States
(12) Patent Application Publication
(10) Pub. No.: US 2025/0374616 A1
(43) Pub. Date: Dec. 4, 2025

(54) SEMICONDUCTOR DEVICE

(71) Applicant: Renesas Electronics Corporation, Tokyo (JP)

(72) Inventors: Kazuhisa MORI, Tokyo (JP); Hiroyoshi KUDOU, Tokyo (JP); Hiroshi YANAGIGAWA, Tokyo (JP); Kodai WADA, Tokyo (JP)

(21) Appl. No.: 19/220,508

(22) Filed: May 28, 2025

(30) Foreign Application Priority Data
May 31, 2024 (JP) 2024-089461

(51) Int. Cl. H10D 62/10; H10D 30/01; H10D 30/66; H10D 62/00

(52) U.S. Cl. CPC H10D 62/111; H10D 30/0297; H10D 30/668; H10D 62/054; H10D 62/127

(57) ABSTRACT

A semiconductor device comprising an n-type epitaxial layer, a plurality of p-type column regions formed in the epitaxial layer so as to be spaced apart from each other in a plan view, and a gate electrode formed between each of the plurality of p-type column regions. The plurality of p-type column region is formed in the epitaxial layer and is composed of first, second and third sub-column regions, which are arranged in order from the side closer to a main surface of the epitaxial layer EP. Additionally, a distance between a position of a maximum impurity concentration of the first sub-column region and a position of a maximum impurity concentration of the second sub-column region is smaller than a distance between the position of the maximum impurity concentration of the second sub-column region and a position of a maximum impurity concentration of the third sub-column region.

### CROSS-REFERENCE TO RELATED APPLICATIONS

The disclosure of Japanese Patent Application No. 2024-089461 filed on May 31, 2024, including the specification, drawings and abstract is incorporated herein by reference in its entirety.

### BACKGROUND

The present invention relates to a semiconductor device, particularly to a technique that is effective when applied to a power semiconductor device.

In a vertical power MOSFET, which is a type of power semiconductor device, a super-junction structure with alternating n-type and p-type columns is being considered to maintain breakdown voltage and reduce on-resistance.

For example, Patent Document 1 (Japanese Unexamined Patent Application Publication No. 2017-139439) describes forming p-type columns in the semiconductor substrate between a plurality of trench gates through m implantations in a semiconductor device with the super-junction structure.

### SUMMARY

When forming p-type columns using ion implantation method, variations in an opening width of a mask used to block ion implantation can easily occur, leading to variations in the breakdown voltage characteristics of the MOSFET. As a result, there is a problem of reduced yield and reliability of a semiconductor device.

Other problems and novel features will become apparent from the description of this specification and the accompanying drawings.

A brief overview of a representative embodiment disclosed in this application is as follows.

A semiconductor device, which is one embodiment, includes an n-type drift region, a plurality of p-type column regions formed in a drift region so as to be spaced apart from each other in a plan view, and a gate electrode formed between each of the plurality of p-type column regions. Here, the plurality of p-type column regions is formed in an epitaxial layer and consist of a first sub-column region, a second sub-column region, and a third sub-column region, arranged in order from the side closer to a main surface of the drift region in a depth direction. Additionally, a distance between a position of a maximum impurity concentration of the first sub-column region and a position of a maximum impurity concentration of the second sub-column region is smaller than a distance between the position of the maximum impurity concentration of the second sub-column region and a position of a maximum impurity concentration of the third sub-column region.

According to one embodiment disclosed in this application, the reliability of the semiconductor device can be improved.

### BRIEF DESCRIPTION OF THE DRAWINGS

FIG. 1 is a cross-sectional view of a semiconductor device according to the embodiment, and a graph showing a relationship between a depth and an impurity concentration in a semiconductor substrate.

FIG. 2 is a graph showing a relationship between the depth and the impurity concentration in the semiconductor substrate in the semiconductor device according to the embodiment.

FIG. 3 is a planar layout of the semiconductor device according to the embodiment.

FIG. 4 is a cross-sectional view during a manufacturing process of the semiconductor device according to the embodiment.

FIG. 5 is a cross-sectional view during the manufacturing process of the semiconductor device following FIG. 4.

FIG. 6 is a cross-sectional view during the manufacturing process of the semiconductor device following FIG. 5.

FIG. 7 is a cross-sectional view during the manufacturing process of the semiconductor device following FIG. 6.

FIG. 8 is a cross-sectional view during the manufacturing process of the semiconductor device following FIG. 7.

FIG. 9 is a cross-sectional view during the manufacturing process of the semiconductor device following FIG. 8.

FIG. 10 is a cross-sectional view during the manufacturing process of the semiconductor device following FIG. 9.

FIG. 11 is a cross-sectional view during the manufacturing process of the semiconductor device following FIG. 10.

FIG. 12 is a cross-sectional view during the manufacturing process of the semiconductor device following FIG. 11.

FIG. 13 is a graph showing an example of a relationship between a column width breakdown voltage of the semiconductor device according to the embodiment.

FIG. 14 is a graph showing an example of a relationship between the column width and the breakdown voltage of the semiconductor device according to the embodiment.

FIG. 15 is a graph showing an example of a relationship between the column width v and the breakdown voltage of the semiconductor device according to the embodiment.

FIG. 16 is a cross-sectional view of the semiconductor device according to a first modified example of the embodiment.

FIG. 17 is a cross-sectional view of the semiconductor device according to a second modified example of the embodiment.

FIG. 18 is a planar layout of the semiconductor device according to a third modified example of the embodiment.

FIG. 19 is a planar layout of the semiconductor device according to a fourth modified example of the embodiment.

FIG. 20 is a cross-sectional view of a semiconductor device according to a Comparative Example 1.

FIG. 21 is a cross-sectional view during a manufacturing process of the semiconductor device according to the Comparative Example 1.

FIG. 22 is a graph showing a relationship between a depth and an impurity concentration in a semiconductor substrate in the semiconductor device according to the Comparative Example 1.

FIG. 23 is a graph showing an example of a relationship between a column width and a breakdown voltage of the semiconductor device according to the Comparative Example 1.

FIG. 24 is a cross-sectional view of a semiconductor device according to a Comparative Example 2.

FIG. 25 is a graph showing an example of a relationship between a column width and a breakdown voltage of the semiconductor device according to the Comparative Example 2.

FIG. 26 is a cross-sectional view of a semiconductor device according to a Comparative Example 3.

### DETAILED DESCRIPTION

In the following embodiments, for convenience, when necessary, the description may be divided into multiple sections or embodiments. However, unless specifically stated otherwise, they are not unrelated to each other; rather, one may be a modification, detail, or supplementary explanation of part or all of the other. Additionally, in the following embodiments, when referring to the number of elements (including quantity, numerical values, amounts, ranges, etc.), unless specifically stated or clearly limited to a specific number in principle, it is not limited to the mentioned number and may be more or less than the mentioned number.

Furthermore, in the following embodiments, the components (including element steps and the like) are not necessarily essential unless specifically stated or considered obviously essential in principle. Similarly, in the following embodiments, when referring to the shapes, positional relationships, etc., of components, unless specifically stated or considered obviously not so in principle, it is assumed to include those substantially approximate or similar in shape, etc. The same applies to the above numerical values and ranges.

Hereinafter, the embodiments will be described in detail with reference to the drawings. In all the drawings for explaining the embodiments, members having the same functions are denoted by the same reference numerals, and repetitive descriptions thereof are omitted. Also, in the following embodiments, descriptions of the same or similar parts will not be repeated in principle except when particularly necessary.

### Embodiment

### (Structure of Semiconductor Device)

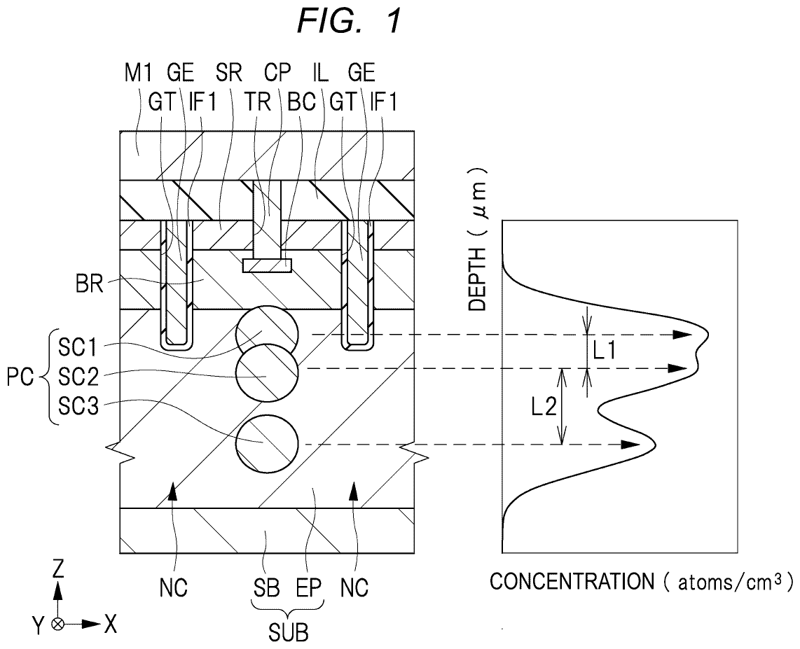

FIG. 1 shows a cross-sectional view of a cell region of a semiconductor device of the present embodiment. The semiconductor device (semiconductor element) of the present embodiment is a vertical power MOSFET (Metal Oxide Semiconductor Field Effect Transistor). A MOSFET is a type of MISFET (Metal Insulator Semiconductor Field Effect Transistor). As shown in FIG. 1, the semiconductor device of the present embodiment has a laminated semiconductor substrate SUB with an upper surface (main surface) and a bottom surface opposite the upper surface. The laminated semiconductor substrate SUB includes a semiconductor substrate SB, which is an n+ type semiconductor layer, and an epitaxial layer EP, which is an n-type semiconductor layer formed on an upper surface of the semiconductor substrate SB. In other words, a bottom surface opposite an upper surface (main surface) of the epitaxial layer EP is in contact with the semiconductor substrate SB, which is an n+ type semiconductor region. The epitaxial layer EP constitutes the drift region.

On the upper surface (main surface) of the epitaxial layer EP, a plurality of trenches (plurality of gate trenches) GT reaching an intermediate depth of the epitaxial layer EP are formed. The trench GT extends, for example, in a Y direction and is arranged in multiple rows in a X direction in the cell region. Additionally, the trench GT extends in a Z direction (thickness direction, depth direction). The X and Y directions referred to in this application are directions along the upper surface of the semiconductor substrate SB and the upper surface (main surface) of the epitaxial layer EP (the main surface of the laminated semiconductor substrate SUB). The X, Y and Z directions are orthogonal to each other in plan view. Here, the X and Y directions may sometimes be referred to as a lateral direction. The Z direction is a direction perpendicular to each of the upper surface (main surface) of the epitaxial layer EP, the upper surface (main surface), and the bottom surface of the laminated semiconductor substrate SUB.

In each trench GT, a gate electrode (trench gate) GE is embedded via a gate insulating film IF1. In other words, side and bottom surfaces of the trench GT are continuously covered by the gate insulating film IF1, for example, made of a silicon oxide film, and the epitaxial layer EP and the gate electrode GE are insulated by the gate insulating film IF1. The gate electrode GE is made of, for example, a polysilicon film. A distance between the main surface of the laminated semiconductor substrate SUB in the Z direction and the bottom surface of the gate electrode GE is 0.8 micrometers or more and less than 1.0 micrometers.

In the epitaxial layer EP between adjacent the trench GT in the X direction, a body region (p-type semiconductor region, channel region) BR is formed. The single body region BR formed between adjacent the trench GT in the X direction is in contact with the side surfaces of each adjacent the trench GT in the X direction. The bottom end of the body region BR is shallower than the bottom end of the trench GT. That is, the body region BR is formed on the epitaxial layer EP (drift layer), which is an n-type semiconductor region.

Additionally, in the epitaxial layer EP between adjacent the trench GT in the X direction, above the body region BR, a source region (n+ type semiconductor region, n+ type diffusion region) SR is formed. The bottom end of the source region SR is in contact with the body region BR. In other words, the source region SR is formed in the body region BR from an upper surface of the body region BR to a predetermined depth. The source region SR is in contact with the side surfaces of adjacent the trench GT in the X direction.

In the epitaxial layer EP below the body region BR between adjacent the trench GT in the X direction, a p-type column region PC consisting of a plurality of sub-column regions SC1, SC2, and SC3 is formed. Sub-column regions SC1, SC2 and SC3 are arranged in the Z direction directly below, for example, the central body region BR between adjacent the trench GT in the X direction. Here, the sub-column regions SC1, SC2 and SC3 are formed in order from the body region BR side to the semiconductor substrate SB side. In the direction perpendicular to the Z direction, widths of each of the sub-column regions SC1, SC2 and SC3 are approximately the same. The width of each of the sub-column regions SC1, SC2 and SC3 in the direction perpendicular to the Z direction is 0.52 micrometers or more and 0.58 micrometers or less.

In the Z direction, a distance between the sub-column region SC1 and the sub-column region SC2 is smaller than a distance between the sub-column region SC2 and the sub-column region SC3. In FIG. 1, the sub-column region SC1 is in contact with the body region BR, but the sub-column region SC1 and the body region BR may be spaced apart from each other. In the Z direction, a distance between the main surface of the laminated semiconductor substrate SUB and the position of a maximum impurity concentration of the sub-column region SC1 is 0.7 micrometers or more and less than 0.9 micrometers.

Since the plurality of trenches GT is repeatedly arranged in multiple rows in the X direction, the p-type column region PC are also formed in multiple rows in the X direction. That is, in the epitaxial layer EP, the plurality of p-type column regions PC is formed so as to be spaced apart from each other in plan view. The gate electrode GE is formed between adjacent the plurality of p-type column regions PC. The plurality of p-type column regions PC and the trench GT, which protrudes to the semiconductor substrate SB side from a bottom surface of the body region BR, are spaced apart from each other in the X direction. The position of the maximum impurity concentration of the sub-column region SC1 is located closer to the main surface of the laminated semiconductor substrate SUB than the bottom surface of the gate electrode GE.

In the X direction, the epitaxial layer EP, which is the n-type semiconductor region between adjacent the plurality of p-type column regions PC, constitutes an n-type column region NC.

An n-type impurity concentration of the source region SR is higher than the n-type impurity concentration of each of the n-type column region NC and the semiconductor substrate SB. Additionally, a p-type impurity concentration of a diffusion region BC is higher than a p-type impurity concentration of the epitaxial layer EP. The trench GT and the gate electrode GE penetrate the source region SR and the body region BR and reach the epitaxial layer EP (drift region) below the body region BR.

On the epitaxial layer EP, the source region SR, and the gate electrode GE, an interlayer insulating film IL is formed. In the interlayer insulating film IL, a contact hole penetrating the interlayer insulating film IL in the Z direction is formed, and the contact hole penetrates the source region SR and reaches the intermediate depth of the body region BR. The recess constituting the contact hole and extending from the main surface of the laminated semiconductor substrate SUB to the intermediate depth of the body region BR constitutes the trench TR.

In the contact hole and the trench TR, a contact plug CP made of, for example, aluminum (Al) or tungsten (W) is embedded. The contact plug CP is formed between adjacent the trench GT in plan view and is located, for example, directly above the p-type column region PC. In other words, in plan view, the contact plug CP is formed at a position overlapping with the p-type column region PC. The contact plug CP penetrates the interlayer insulating film IL and reaches the body region BR.

In the body region BR, the diffusion region (body contact region) BC, which is the p+ type semiconductor region, is formed, spaced apart from the epitaxial layer EP and the trench GT, and in contact with a bottom surface of the contact plug CP. The impurity concentration of the diffusion region BC is higher than the impurity concentration of any of the body region BR, the sub-column regions SC1, SC2 and SC3. The contact plug CP is connected to a side surface of the source region SR and an upper surface of the diffusion region BC.

On the interlayer insulating film IL and the contact plug CP, a wiring M1 made of, for example, aluminum (Al) is formed. The contact plug CP and the wiring M1 may be formed separately or may be integrated with each other.

In the X direction, the p-type column region PC and the n-type column region NC (n-type epitaxial layer EP) are alternately arranged. In other words, the plurality of p-type column regions PC and the drift region (epitaxial layer EP) between the plurality of p-type column regions PC are arranged in parallel at a predetermined interval in plan view. The p-type column regions PC and the n-type column regions NC, which are alternately arranged in the lateral direction, constitute a super-junction structure. The gate electrode GE, the source region SR, the body region BR, the n-type column region NC, and epitaxial layer EP, along with the n+ type semiconductor region (drain region) composed of the semiconductor substrate SB, form an n-channel type vertical power MOSFET.

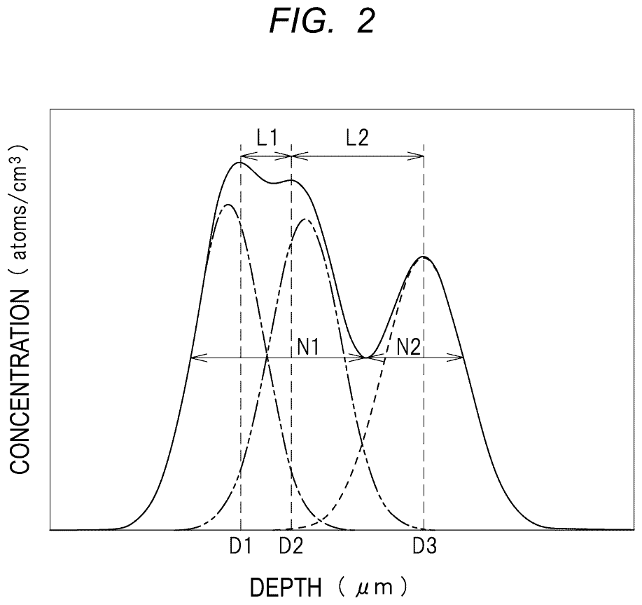

FIG. 1 shows a cross-sectional view including a vertical power MOSFET, along with a graph indicating the concentration distribution of p-type impurities in the laminated semiconductor substrate SUB. The vertical axis of the graph corresponds to a depth position of the laminated semiconductor substrate SUB in the cross-sectional view. In other words, in the graph, the vertical axis indicates the depth from the main surface of the laminated semiconductor substrate SUB, and the horizontal axis indicates the concentration of p-type impurities. Additionally, FIG. 2 presents the graph from FIG. 1 with its orientation changed. In this graph shown in FIG. 2, the vertical axis indicates the concentration of p-type impurities in the laminated semiconductor substrate SUB, and the horizontal axis indicates the depth from the main surface of the laminated semiconductor substrate SUB. In the graph of FIG. 1, the positive values of depth increase from the top to the bottom, while in the graph of FIG. 2, the positive values of depth increase from the left to the right. These graphs illustrate the concentration distribution in the region where the p-type column region PC is formed.

In FIG. 2, the concentration distribution of all impurities constituting each of the sub-column regions SC1, SC2 and SC3 are shown with a solid line. The concentration distribution of impurities introduced by ion implantation when forming the sub-column region SC1 is shown with a one-dot chain line. The concentration distribution of impurities introduced by ion implantation when forming the sub-column region SC2 is shown with a two-dot chain line. The concentration distribution of impurities introduced by ion implantation when forming the sub-column region SC3 is shown with a broken line.

As shown in FIGS. 1 and 2, in the laminated semiconductor substrate SUB, there are three maximum positions (concentration peaks) of impurity concentration corresponding to each of the sub-column regions SC1, SC2 and SC3. In the Z direction, the depth at which the impurity concentration of the sub-column region SC1 is maximum is D1, the depth at which the impurity concentration of the sub-column region SC2 is maximum is D2, and the depth at which the impurity concentration of the sub-column region SC3 is maximum is D3. In the Z direction, the distance L1 between the depth D1 and the depth D2 is smaller than the distance L2 between the depth D2 and the depth D3. In other words, the distance L1 between the maximum position of the impurity concentration of the sub-column region SC1 and the maximum position of the impurity concentration of the sub-column region SC2 is smaller than the distance L2 between the maximum position of the impurity concentration of the sub-column region SC2 and the maximum position of the impurity concentration of the sub-column region SC3. For example, the depth at which the impurity concentration of the sub-column region SC1 is maximum is not a position where an impurity concentration is maximum in the concentration distribution shown by the one-dot chain line in FIG. 2. The depth at which the impurity concentration of the sub-column region SC1 is maximum is the maximum position of the impurity concentration of the sub-column region SC1 in the region where the sub-column region SC1 overlaps with other sub-column regions such as SC2. The distance L1 is 0.3 micrometers or more and less than 0.6 micrometers, and the distance L2 is 0.6 micrometers or more and less than 1.0 micrometers.

In other words, as shown in FIG. 2, a width N1 in the depth direction (Z direction) of the impurity region formed integrally by the sub-column regions SC1 and SC2 is larger than a width N2 in the depth direction of the sub-column region SC3. The width N1 is a distance from a position indicating a minimum impurity concentration between the maximum position of the impurity concentration of the sub-column region SC2 and the maximum position of the impurity concentration of the sub-column region SC3 to a position where an impurity concentration becomes the minimum impurity concentration in the region shallower than the maximum position (depth D1) of the impurity concentration of the sub-column region SC1 (the region on the main surface of the laminated semiconductor substrate SUB side). The width N2 is a distance from a position indicating the minimum impurity concentration between the maximum position of the impurity concentration of the sub-column region SC2 and the maximum position of the impurity concentration of the sub-column region SC3 to a position where an impurity concentration becomes the minimum impurity concentration in the region deeper than the maximum position (depth D3) of the impurity concentration of the sub-column region SC3 (a region on the bottom surface of the laminated semiconductor substrate SUB side). The width N1 is 0.5 micrometers or more and less than 1.0 micrometers, and the width N2 is 0.2 micrometers or more and less than 0.5 micrometers.

Furthermore, the positions of the sub-column regions SC1 and SC2 in the depth direction are relatively close. Therefore, the impurity concentration in the region where the sub-column regions SC1 and SC2 overlap is higher than the impurity concentration at the maximum position of the impurity concentration of the sub-column region SC3. Here, the impurity concentration of the sub-column region SC1 shown by the one-dot chain line is higher than the impurity concentration of the sub-column region SC2 shown by the two-dot chain line, and the impurity concentration of the sub-column region SC2 shown by the two-dot chain line is higher than the impurity concentration of the sub-column region SC3 shown by the broken line. The impurity concentration in the region where the sub-column regions SC1 and SC2 overlap is 2 to 5 times: higher than the impurity concentration at the maximum position of the impurity concentration of the sub-column region SC3.

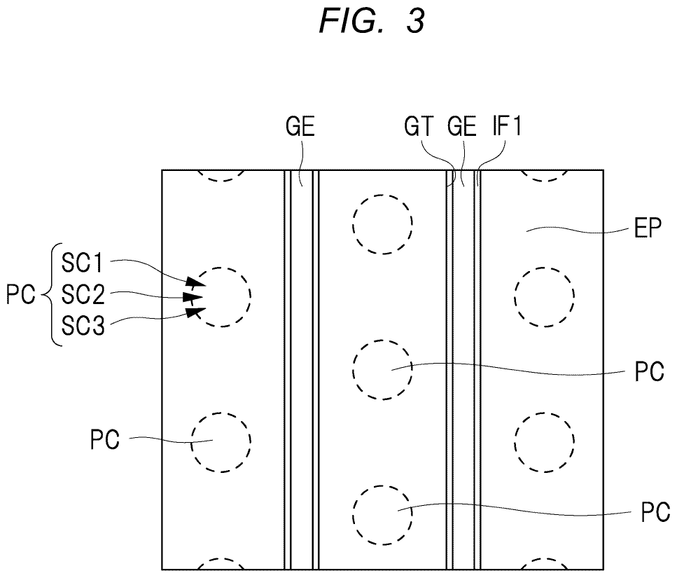

FIG. 3 shows the planar layout of the semiconductor device of the present embodiment. In FIG. 3, only the epitaxial layer EP, the trench GT, the gate insulating film IF1, the gate electrode GE, the p-type column region PC, and the sub-column regions SC1, SC2 and SC3 are shown. In plan view, the sub-column region SC1 and the sub-column regions SC2 and SC3 located below it overlap each other. In this application, plan view refers to viewing the object in the Z direction. In FIG. 3, the sub-column regions SC1, SC2 and SC3 are shown with broken lines.

As shown in FIG. 3, the trench GT and the gate electrode GE extend in the Y direction. The sub-column regions SC1, SC2 and SC3 are formed at positions spaced apart from the trench GT and the gate electrode GE, and each has a planar shape that is, for example, circular. The p-type column region PC, composed of the sub-column regions SC1, SC2 and SC3 formed in the Z direction, is arranged in the Y direction. Additionally, a row of the p-type column regions PC arranged in the Y direction is positioned in a half-period shifted position in the Y direction relative to another row of the p-type column regions PC located across the gate electrode GE in plan view. In other words, the plurality of p-type column regions PC are arranged in a staggered manner, spaced apart from each other.

(Operation of Vertical Power MOSFET with Super-Junction Structure)

In the present embodiment, the super-junction structure is adopted, in which the p-type column region PC and the n-type column region NC (the n-type epitaxial layer EP adjacent to the p-type column region PC) are periodically arranged. By forming a vertical power MOSFET on such the laminated semiconductor substrate SUB, it is possible to reduce the on-resistance while ensuring high withstand voltage.

That is, in the off state, the boundary region between the p-type column region PC and the n-type column region NC in the lateral direction, that is, from the pn junction extending in the Z direction, a depletion layer extends laterally in the n-type column region NC. In other words, the depletion layers extending from the sides of adjacent the p-type column regions PC come into contact with each other, thereby blocking the current path in the drift region.

Therefore, in the vertical power MOSFET with the super-junction structure, even if the impurity concentration of the epitaxial layer EP (drift region), which serves as the current path, is increased to reduce the on-resistance, the breakdown voltage can be ensured by the depletion layer spreading laterally from the pn junction. Thus, it is possible to reduce the on-resistance while ensuring high withstand voltage.

In the semiconductor device shown in FIG. 1, the epitaxial layer EP, which is the drift region, is in contact with the bottom surface of the trench GT. When the vertical power MOSFET is in the on state, a positive voltage is applied to the gate electrode GE, causing an inversion layer (channel) to form in the body region BR at the location in contact with the side surface of the trench GT. As a result, current flows between the source region SR and the semiconductor substrate SB, which is the drain region, via the epitaxial layer EP and the inversion layer. To ensure this current path, the p-type column region PC and the trench GT need to be spaced apart from each other. Additionally, to ensure the breakdown voltage in the off state, the maximum position (depth D1) of the impurity concentration of the sub-column region SC1 is located closer to the main surface of the laminated semiconductor substrate SUB than the bottom surface of the gate electrode GE.

By arranging the plurality of p-type column regions PC in the staggered manner as shown in FIG. 3, a distance between adjacent the p-type column regions PC in plan view becomes almost equal in any direction. This makes it easier for the depletion layers extending from the sides of adjacent the p-type column regions PC to come into contact with each other in the off state, thereby enhancing the reliability of ensuring the breakdown voltage.

### (Method of Manufacturing the Semiconductor Device)

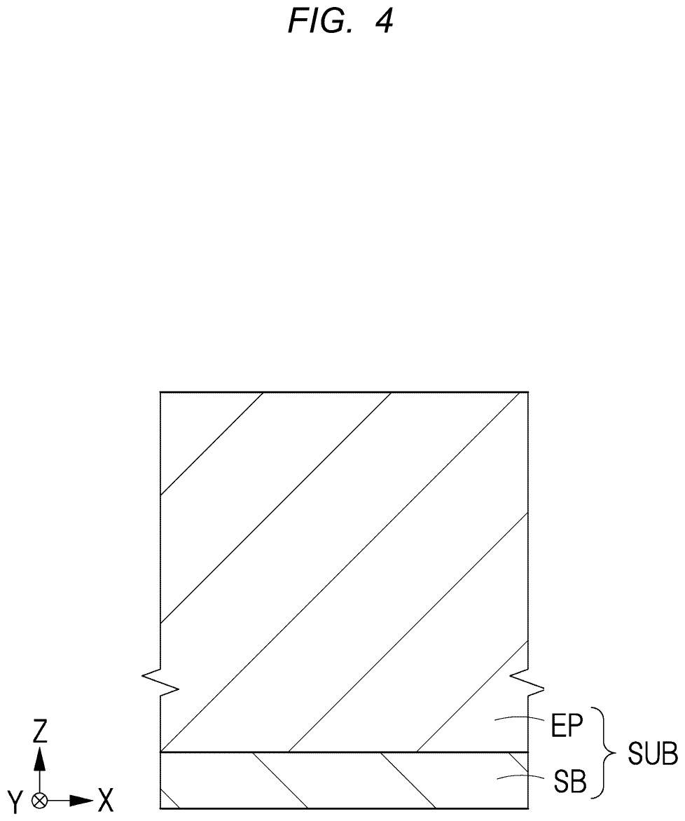

Below, the method of manufacturing the semiconductor device of the present embodiment will be described with reference to FIGS. 4 to 12. FIGS. 4 to 12 are cross-sectional views during the manufacturing process of the semiconductor device of the present embodiment.

First, as shown in FIG. 4, prepare the laminated semiconductor substrate (semiconductor wafer) having a SUB structure, specifically an n+ type semiconductor laminated substrate SB with the epitaxial layer EP made of the n-type semiconductor layer formed on the upper surface of the semiconductor substrate SB. The n-type impurity concentration of the epitaxial layer EP is lower than that of the semiconductor substrate SB. The laminated semiconductor substrate SUB, consisting of the epitaxial layer EP and the semiconductor substrate SB, will later be diced into multiple chip areas that become semiconductor chips. In plan view, each chip area has a cell region at its center where elements are formed. FIGS. 4 to 12 show the structure of the cell region during the manufacturing process. The laminated semiconductor substrate SUB includes the upper surface (main surface), which is the main surface of the epitaxial layer EP, and the bottom surface of the semiconductor substrate SB.

The semiconductor substrate SB is formed by introducing n-type impurities such as phosphorus (P) into monocrystalline silicon. The resistance of the semiconductor substrate SB is, for example, 1.5 Milliohm centimeter or less. The epitaxial layer EP is formed on the semiconductor substrate SB using epitaxial growth method. The epitaxial layer EP mainly consists of silicon (Si). During the epitaxial growth, p-type impurities (for example, phosphorus (P)) are included in the epitaxial layer EP.

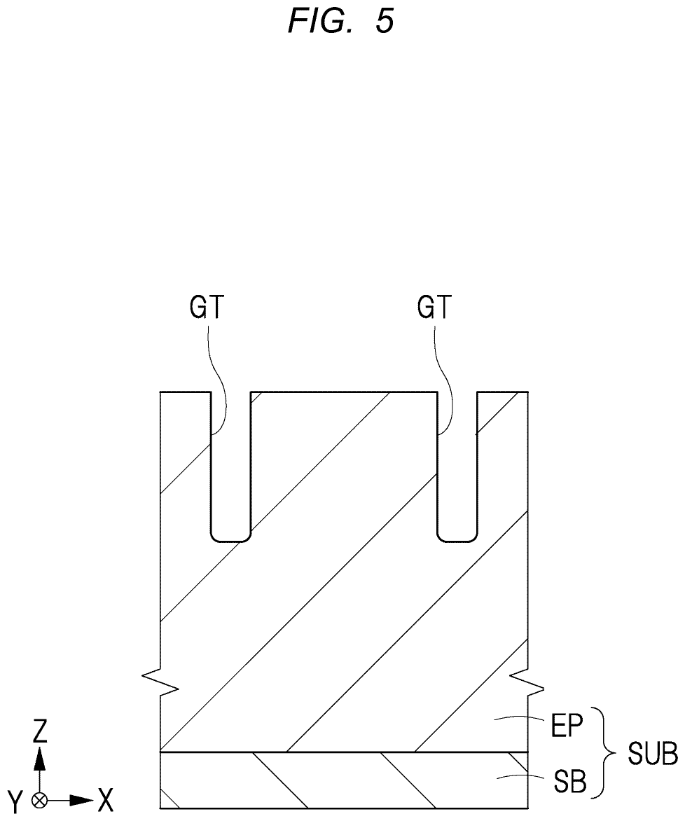

Next, as shown in FIG. 5, form the plurality of trenches GT on the main surface of the epitaxial layer EP. That is, stack multiple insulating films (not shown) on the epitaxial layer EP. These insulating films include, for example, a silicon oxide film formed by an oxidation method and a silicon nitride film formed by a CVD (Chemical Vapor Deposition) method. Subsequently, form a photoresist film (not shown) on these insulating films. The photoresist film is a resist pattern with through-holes. Then, perform dry etching using the photoresist film as a mask (etching prevention mask, etching mask). This removes part of the multiple insulating films and exposes the main surface of the epitaxial layer EP. Then, perform dry etching using the photoresist film and the multiple insulating films as masks. This forms the plurality of trenches GT reaching a mid-depth of the epitaxial layer EP from its main surface.

The trench GT, having a predetermined width and depth, extend in the Y direction and are arranged in multiple rows in the X direction. The bottom of the trench GT does not reach the interface between the epitaxial layer EP and the semiconductor substrate SB. The trench GT is a gate trench in which the gate electrodes will be filled in later processes.

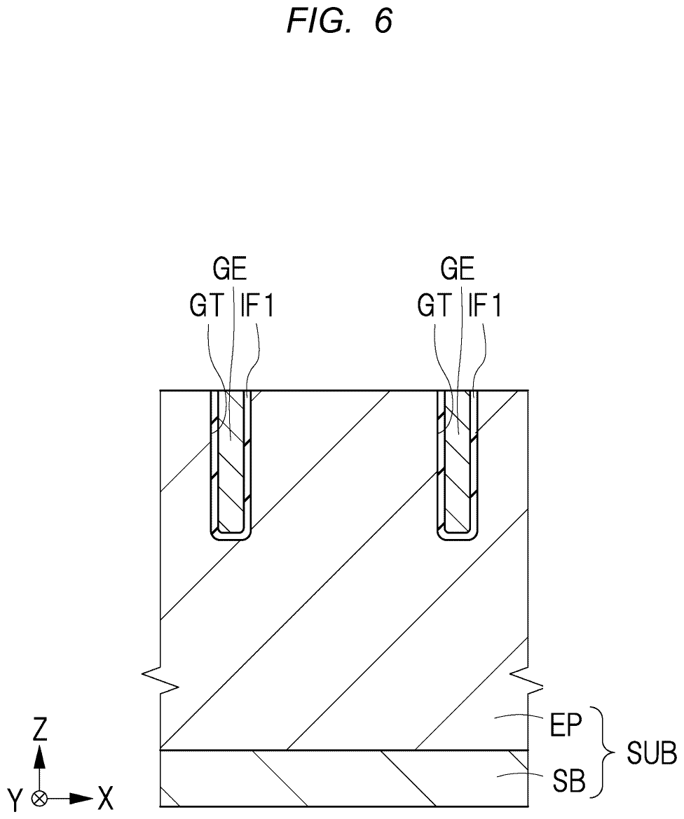

Next, as shown in FIG. 6, remove the photoresist film and the insulating films on the epitaxial layer EP. Then, using an oxidation method, form the gate insulating film IF1 covering the sides and bottom of the trench GT and the main surface of the epitaxial layer EP outside the trench GT. The gate insulating film IF1 is made of, for example, a silicon oxide film. Then, using a CVD method or the like, form a silicon film on the gate insulating film IF1, thereby completely filling the trench GT. Subsequently, perform etch-back to remove the silicon film and the gate insulating film IF1 on the main surface of the epitaxial layer EP, except inside the trench GT. This forms the gate electrode GE made of the silicon film inside the trench GT via the gate insulating film IF1, which serves as a gate dielectric film.

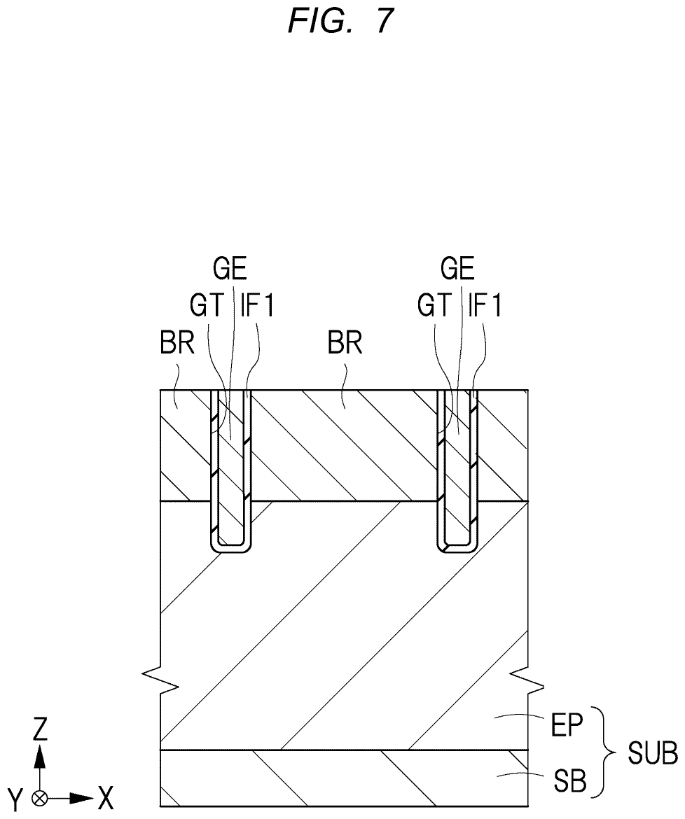

Next, as shown in FIG. 7, perform ion implantation on the main surface of the epitaxial layer EP to implant p-type impurities (for example, boron (B)). By introducing p-type impurities into the epitaxial layer EP in this way, form the p-type body region BR shallower than the trench GT between adjacent the trench GT. The body region BR is in contact with the sides of the trench GT and extends along these sides. The depth of the body region BR is shallower than that of the gate electrode GE.

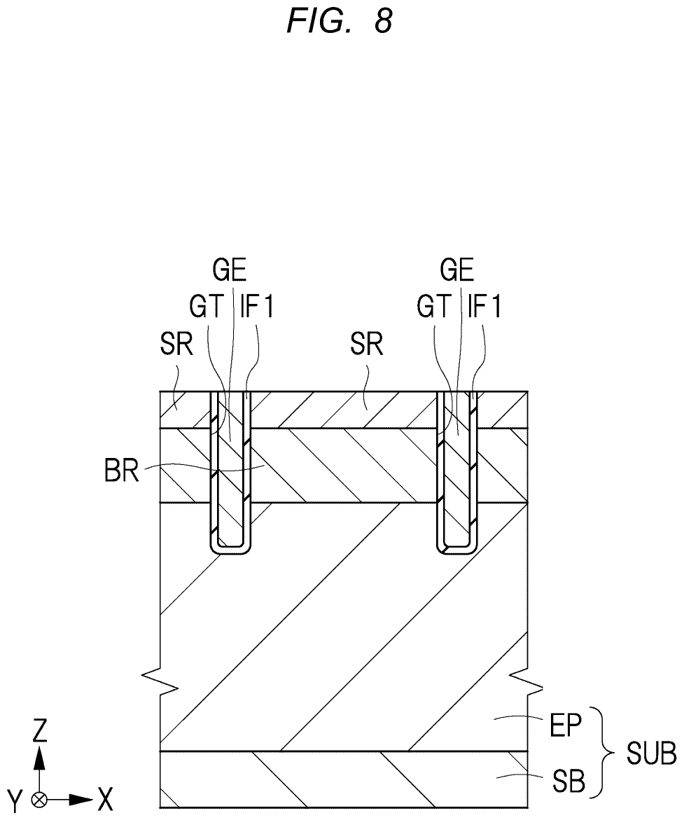

Next, as shown in FIG. 8, perform ion implantation on the main surface of the epitaxial layer EP to implant n-type impurities (for example, arsenic (As)) into the epitaxial layer EP (in the body region BR). By introducing n-type impurities into the epitaxial layer EP in this way, form the n+ type source region SR shallower than the body region BR between adjacent the trench GT. The source region SR is in contact with the sides of the trenches GT and the body region BR. The n-type impurity concentration of the source region SR is higher than that of the drift region, which is the epitaxial layer EP.

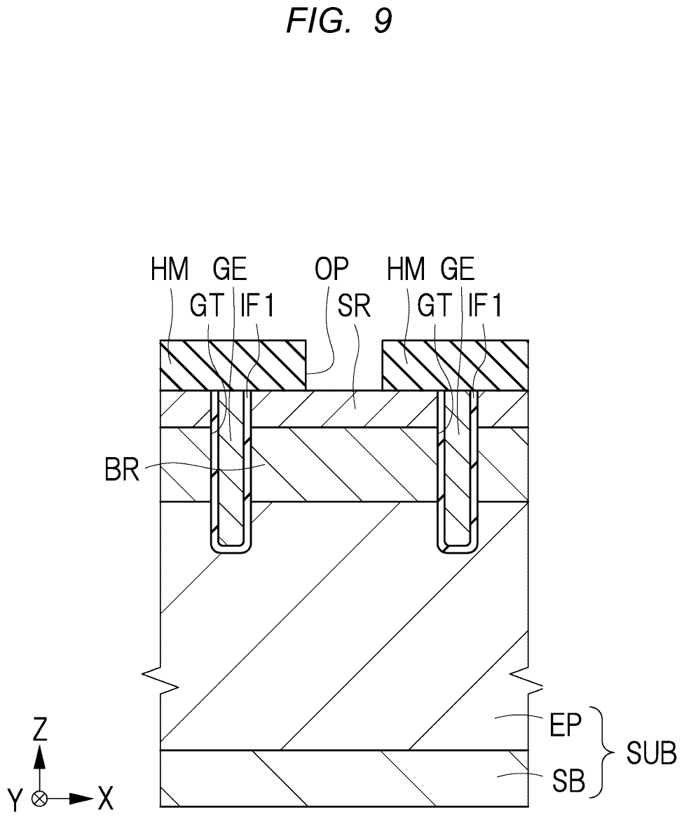

Next, as shown in FIG. 9, form the insulating film on each of the epitaxial layer EP, the gate insulating film IF1, and the gate electrode GE using a CVD method or the like. The insulating film is made of, for example, silicon oxide. Then, using photolithography and dry etching techniques, open a part of the insulating film. This partially exposes the main surface of the epitaxial layer EP (the main surface of the laminated semiconductor substrate SUB) where the source region SR is formed. This forms a hard mask (protective film) HM made of the insulating film. An opening OP formed in the hard mask HM by the etching process is located over the region between adjacent the trench GT in the X direction.

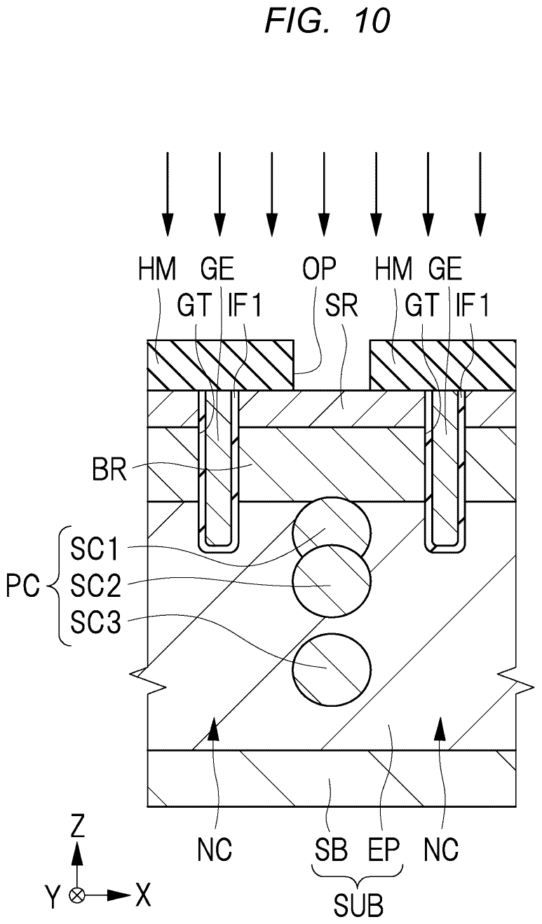

Next, as shown in FIG. 10, perform ion implantation in multiple stages (multi-stage) using the hard mask HM as a mask (ion implantation blocking mask, impurity introduction mask). This introduces p-type impurities (for example, boron (B)) into the epitaxial layer EP. Here, implant p-type impurities three times at different implantation energies into the epitaxial layer EP below the opening OP and below the body region BR. That is, perform multi-stage implantation by gradually changing an energy of the ion implantation. By performing this ion implantation in three stages, the sub-column regions SC1, SC2 and SC3 are formed at different depths in the epitaxial layer EP. The sub-column region SC1 is formed at a shallower position than the sub-column region SC2, and the sub-column region SC2 is formed at a shallower position than the sub-column region SC3. In this way, the sub-column regions SC1, SC2 and SC3 formed in the epitaxial layer EP and arranged in the Z direction constitute the single p-type column region PC. The p-type column region PC is formed in multiple rows in the Z direction between adjacent the trench GT (see FIG. 3).

Here, the sub-column regions SC1, SC2 and SC3 are not formed at equal intervals in the Z direction. That is, by making the energy during ion implantation for forming the sub-column region SC3 relatively strong, the sub-column region SC3 is formed at a relatively deep position. In other words, the distance between the maximum impurity concentration position of the sub-column region SC1 and that of the sub-column region SC2 is smaller than the distance between the maximum impurity concentration position of the sub-column region SC2 and that of the sub-column region SC3. Also, the maximum impurity concentration position of the sub-column region SC1 is located closer to the main surface of the laminated semiconductor substrate SUB than the bottom surface of the gate electrode GE. The sub-column regions SC1, SC2 and SC3 can be formed in any order.

The adjacent p-type column regions PC are separated by the n-type epitaxial layer EP. The epitaxial layer EP between adjacent p-type column regions PC constitutes the n-type column region NC.

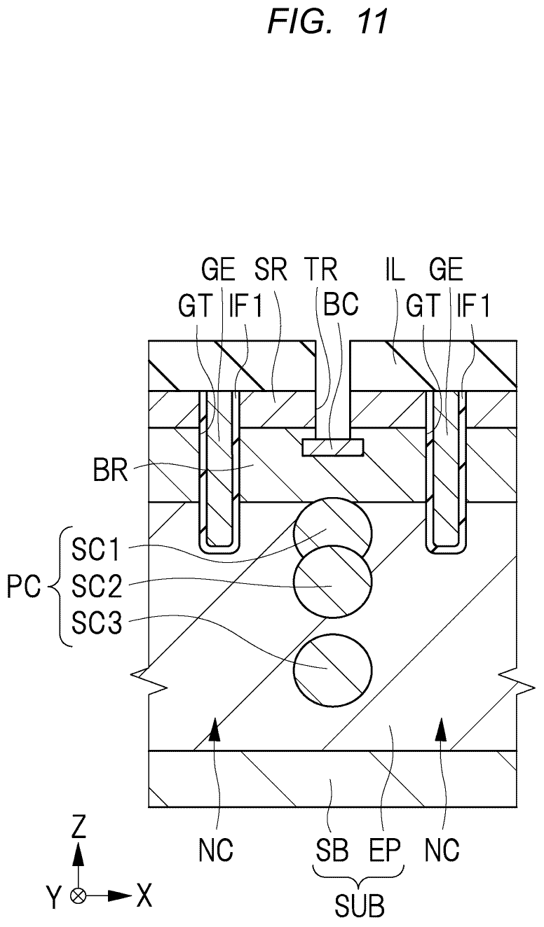

Next, as shown in FIG. 11, after removing the hard mask HM, form the interlayer insulating film IL on the insulating film IF1. The interlayer insulating film IL mainly consists of silicon oxide and can be formed by a CVD method, for example. Then, using a CMP (Chemical Mechanical Polishing) method, polish an upper surface of the interlayer insulating film IL to planarize it. Subsequently, pattern the interlayer insulating film IL using photolithography and dry etching techniques. This forms contact holes (openings) that penetrate the interlayer insulating film IL and expose the main surface of the epitaxial layer EP where the source region SR is formed.

Then, perform etching using the interlayer insulating film IL as a mask to recess the main surface of the epitaxial layer EP exposed at the bottom of each of the plurality of contact holes. This forms the plurality of trenches TR deeper than the bottom surface of the source region SR and shallower than the bottom surface of the body region BR. The bottom surface of the trench TR exposes the body region BR.

Next, perform ion implantation using the interlayer insulating film IL as a mask. Here, implant p-type impurities (for example, BF2 (boron fluoride)) into the body region BR directly below each of the plurality of contact holes. In this way, introduce p-type impurities into the body region BR. This forms the diffusion region (body contact region) BC, which is the p+ type semiconductor region, at a position separated from the trench GT, extending from the bottom surface of the trench TR to a mid-depth of the body region BR. Then, perform heat treatment on the semiconductor wafer. This heat treatment diffuses the impurities in each of the source region SR and the diffusion region BC.

In this way, the super-junction structure is formed in which the p-type column region PC and the n-type epitaxial layer EP (n-type column region NC) are alternately arranged in the lateral direction. The gate electrode GE, the source region SR, the body region BR, the n-type column region NC, the epitaxial layer EP, and the n+-type semiconductor region consisting of the semiconductor substrate SB constitute a vertical power MOSFET.

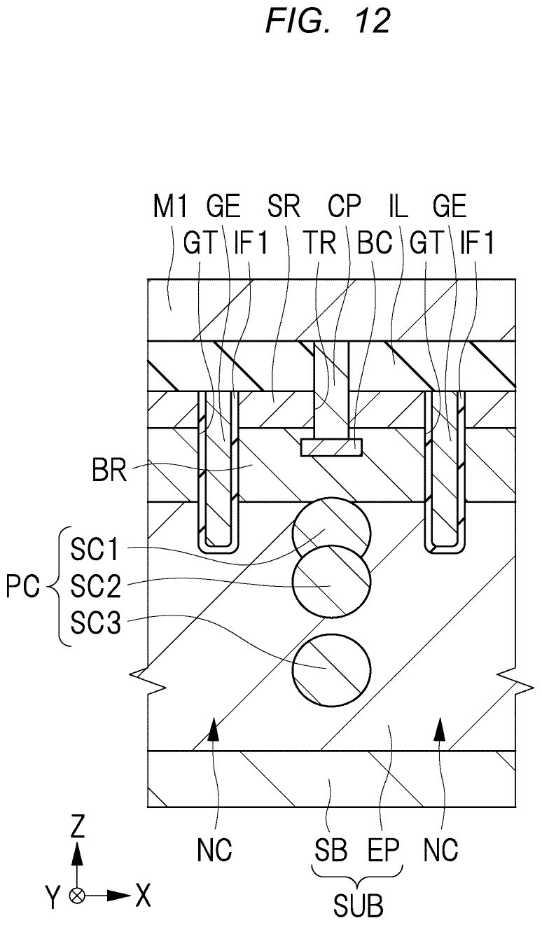

Next, as shown in FIG. 12, a metal film is formed on the interlayer insulating film IL. Specifically, a TiN (titanium nitride) film, Ti (titanium) film, and W (tungsten) film are sequentially formed using methods such as sputtering. This results in the embedding of these metal films in each contact hole. Subsequently, these metal films on the interlayer insulating film IL are removed, for example, by the CMP method, exposing the upper surface of the interlayer insulating film IL. This forms the contact plug (conductive connection) CP from the remaining metal films in each contact hole. In FIG. 12, these metal films constituting the contact plug CP are collectively shown as a single contact plug CP.

Subsequently, a metal film made of Al (aluminum) is formed on the interlayer insulating film IL and the contact plug CP using methods such as sputtering. This metal film is then patterned using photolithography and dry etching techniques to form the plurality of wirings M1. One of the plurality of wirings M1 constitutes a source electrode electrically connected to the source region SR and the diffusion region BC via the contact plug CP. Another of the plurality of wirings M1 constitutes a gate lead-out electrode in an unillustrated region.

Subsequently, although not illustrated, a surface protective film is formed to cover the plurality of wirings M1, for example, using the CVD method. This surface protective film is then patterned to expose parts of upper surfaces of each of the plurality of wirings M1. These exposed parts become external connection areas (e.g., gate pad, source pad).

Subsequently, a drain electrode (not shown) is formed to cover the bottom surface of the laminated semiconductor substrate SUB. Here, for example, the bottom surface side of the laminated semiconductor substrate SUB is oriented upwards, and a metal film is formed by sputtering or deposition methods. This allows the formation of the drain electrode from the metal film.

Thereafter, the semiconductor wafer is diced through a dicing process, dividing into each of the multiple chip areas of the semiconductor wafer. In other words, one semiconductor chip is obtained from one chip area, and multiple semiconductor chips are obtained from the semiconductor wafer. Through the above processes, the semiconductor device of the present embodiment can be formed.

### Effects of the Embodiment

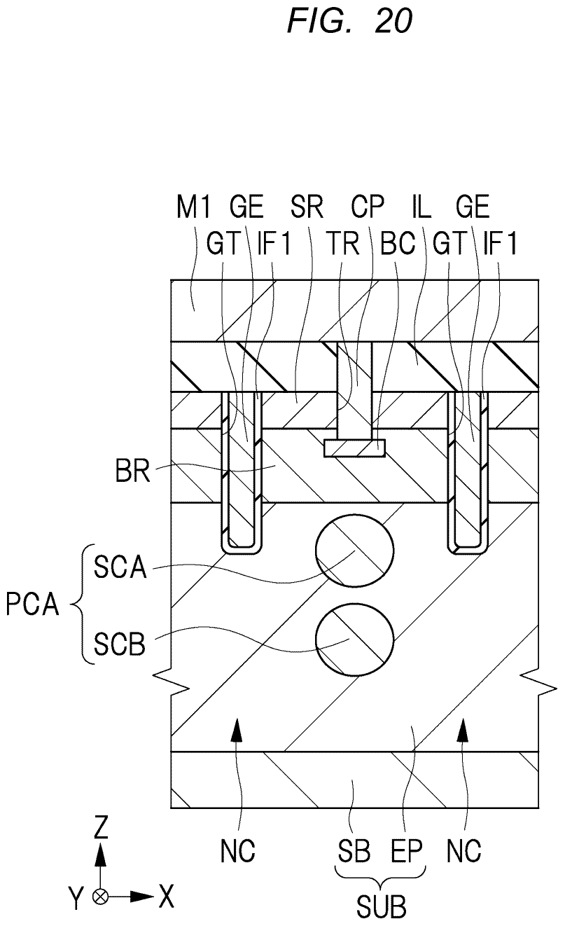

FIG. 20 shows a cross-sectional view of a semiconductor device of a Comparative Example 1. The semiconductor device of the Comparative Example 1 is a vertical power MOSFET with the super-junction structure. The semiconductor device of the Comparative Example 1 includes a plurality of p-type column regions PCA with p-type sub-column regions SCA and SCB formed by ion implantation. The semiconductor device of the Comparative Example 1 differs from the present embodiment in that it has two sub-column regions.

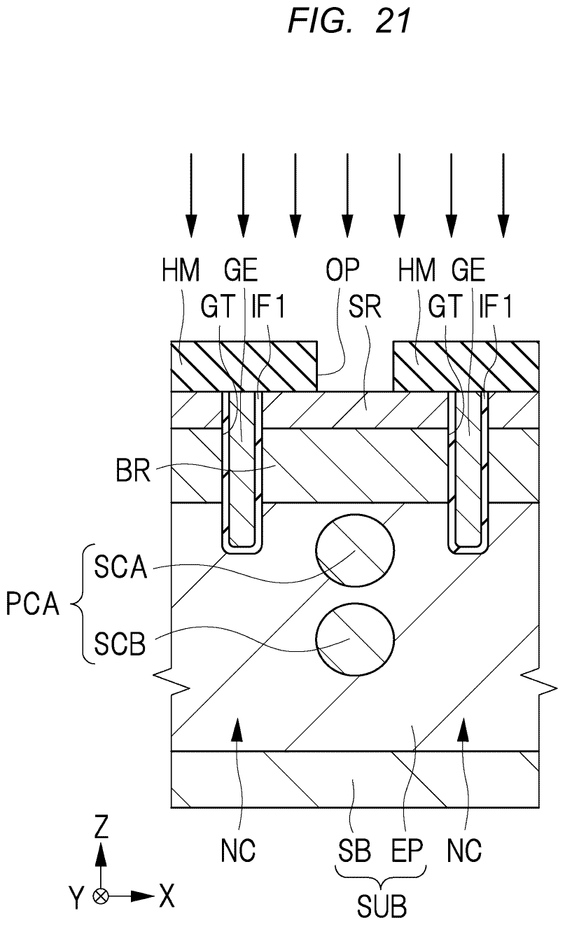

FIG. 21 shows a cross-sectional view during the manufacturing process of the semiconductor device of the Comparative Example 1. FIG. 21 corresponds to the sub-column region formation process described using FIG. 10 in the above embodiment. In the manufacturing process of the semiconductor device of the Comparative Example 1, ion implantation is performed using the hard mask HM as a mask, forming the sub-column regions SCA and SCB under the opening OP of the hard mask HM.

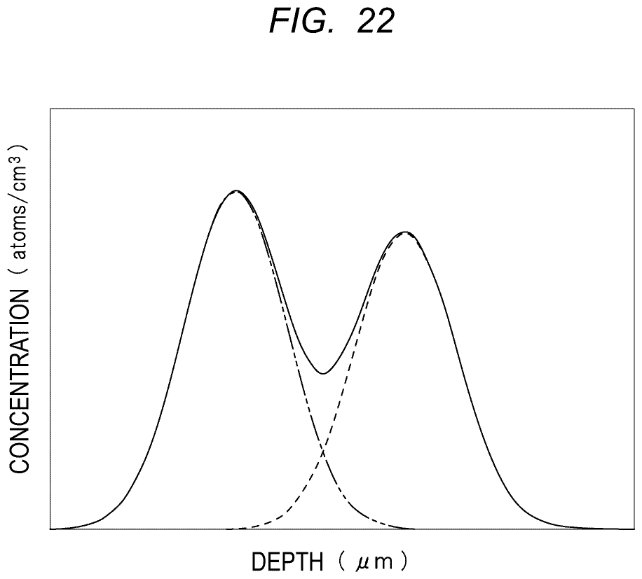

FIG. 22 shows a graph of the relationship between depth and the impurity concentration in a semiconductor substrate of the semiconductor device of the Comparative Example 1. The vertical axis of the graph indicates the concentration of p-type impurities in the laminated semiconductor substrate SUB, and the horizontal axis indicates the depth from the main surface of the laminated semiconductor substrate SUB. These graphs show the concentration distribution in the region where the p-type column region PCA is formed. In FIG. 22, the concentration distribution of impurities introduced by ion implantation when forming the sub-column region SCA is shown by a two-dot chain line. The concentration distribution of impurities introduced by ion implantation when forming the sub-column region SCB is shown by a dashed line.

Here, in the case of a power semiconductor with a mixed vertical power MOSFET and low-high voltage CMOS (Complementary MOS) transistors, the breakdown voltage of the vertical power MOSFET is essential for both-side standards. The term “both-side standards” here refers to the definition of both lower and upper limits for the breakdown voltage by standards. In contrast, a standard that defines only a lower limit for the breakdown voltage is called a one-side standard. To protect internal circuit elements from reverse electromotive force generated when the drive circuit of an inductive load is off, the breakdown voltage of the vertical power MOSFET needs to be lower than that of the circuit configuration elements. For example, the breakdown voltage of the vertical power MOSFET is required to be 35V or more and 50V or less. Therefore, to meet these both-side standards, it is necessary to suppress the occurrence of breakdown voltage variations in the vertical power MOSFET.

However, the semiconductor device of the Comparative Example 1 has a problem in that breakdown voltage variations are likely to occur.

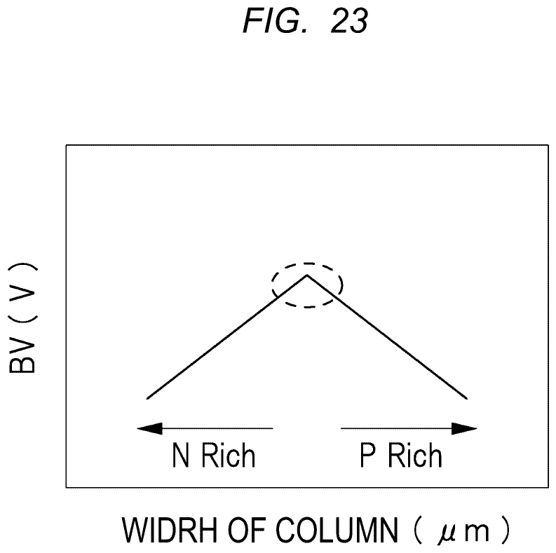

FIG. 23 shows an example of the relationship between a column width and breakdown voltage of the semiconductor device of the Comparative Example 1 in a graph. The horizontal axis of the graph indicates the column width, and the vertical axis indicates the breakdown voltage of the vertical power MOSFET. The width of the column region on the horizontal axis specifically refers to an opening width of the opening OP of the hard mask HM, which greatly influences the determination of the width in the lateral direction of the sub-column region.

As can be seen from the graph in FIG. 23, when the column width is small relative to the center of the graph, the p-type column region PCA is in an N-rich state with relatively more n-type impurities, and the breakdown decreases. In contrast, when the column width is large relative to the center of the graph, the p-type column region PCA is in a P-rich state with relatively more p-type impurities, and in this case, the breakdown voltage also decreases. In FIG. 23, the region corresponding to the center of the graph's horizontal axis (enclosed by a dashed line) has a high breakdown voltage because the charge balance between n-type and p-type impurities is maintained. However, because the range of column width where the charge balance is maintained is extremely small, in the Comparative Example 1, when variations in column width occur, variations in the breakdown voltage of the vertical power MOSFET are likely to occur. In other words, when variations in column width are likely to occur, it is not possible to stabilize the breakdown voltage. Variations in column width are caused by variations in the opening width of the opening OP of the hard mask HM and variations in other manufacturing processes.

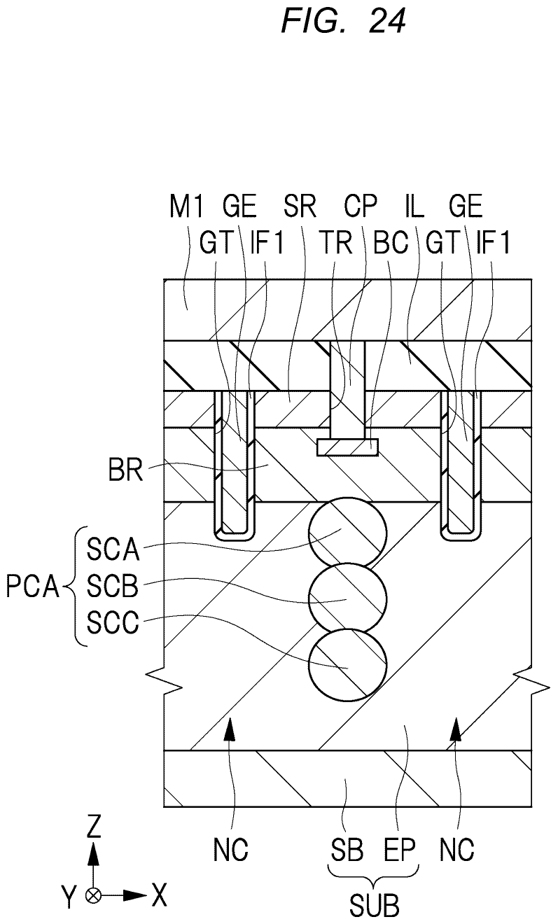

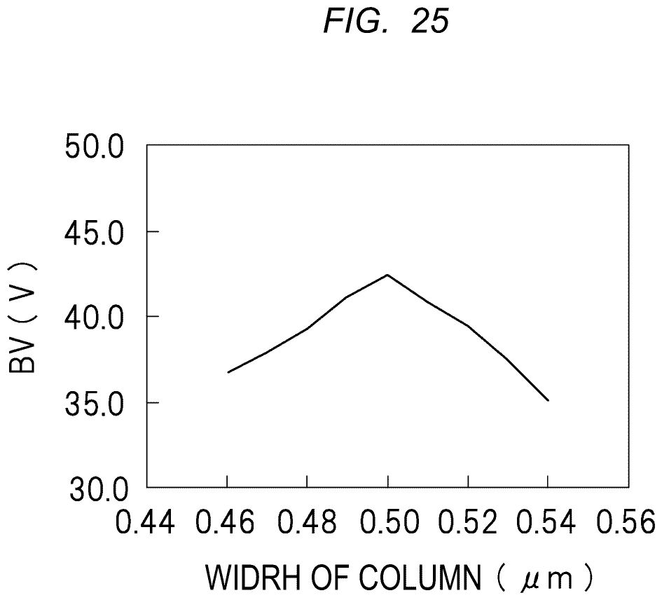

Therefore, as shown in FIG. 24, the inventors considered constructing the p-type column region PCA with sub-column regions SCA, SCB and SCC arranged at equal intervals in the Z direction. FIG. 24 is a cross-sectional view of a semiconductor device of a Comparative Example 2. FIG. 25 shows a graph of the relationship between the column width and breakdown voltage of the semiconductor device of the Comparative Example 2. FIG. 25 shows the column width dependency of the breakdown voltage obtained from experiments conducted by the inventors. Even when three sub-column regions SCA, SCB, and SCC are formed at equal intervals as in the Comparative Example 2, as shown in FIG. 25, the breakdown voltage characteristics have a peak. In other words, because the breakdown voltage changes significantly with the size of the column width, it is not possible to stabilize the breakdown voltage.

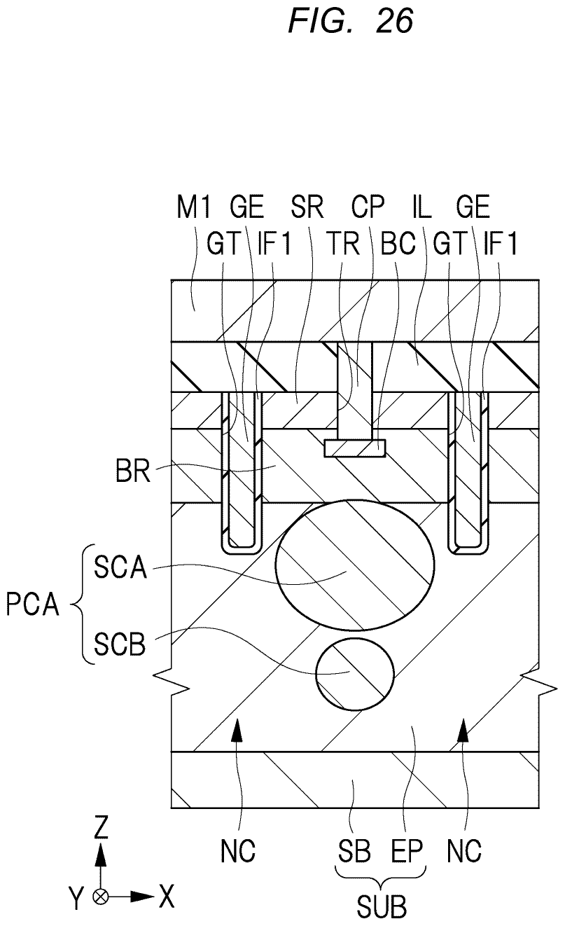

Furthermore, as shown in FIG. 26, the inventors considered forming the sub-column region SCA on the main surface of the laminated semiconductor substrate SUB side of the sub-column regions constituting the p-type column region PCA with a higher concentration and a larger width in the lateral direction than the lower sub-column region SCB. However, in this case, a problem arises in that the on-resistance, which is an important characteristic of the vertical power MOSFET, increases. Specifically, here, the sub-column region SCA adjacent to the gate electrode GE protruding below the bottom surface of the body region BR in the X direction is formed with a high concentration and a large width in the lateral direction. In this case, a width of the epitaxial layer EP (drift region) between the sub-column region SCA and the trench GT, which serves as the current path in the on-state vertical power MOSFET, narrows. As a result, the on-resistance of the vertical power MOSFET increases.

In contrast, in the present embodiment, one p-type column region PC is constructed with the plurality of column regions including the sub-column regions SC1, SC2 and SC3. Additionally, here, the distance between the sub-column regions SC1 and SC2 is smaller than the distance between the sub-column regions SC2 and SC3.

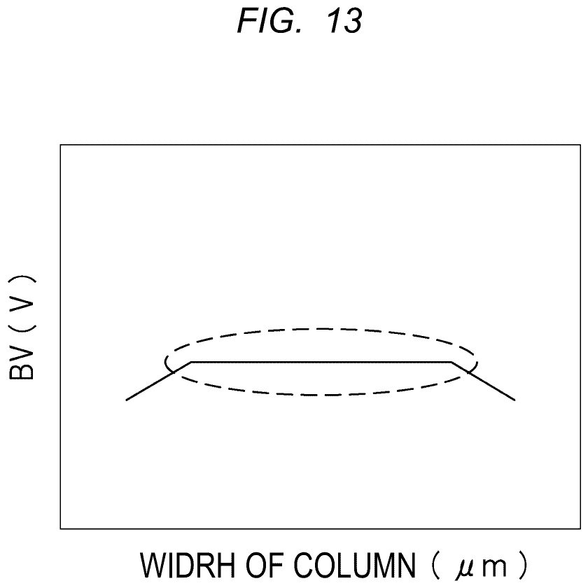

Here, FIG. 13 shows a graph of an example of the relationship between the column width and breakdown voltage of the semiconductor device of the present embodiment. The horizontal axis of the graph indicates the column width, and the vertical axis indicates the breakdown voltage of the vertical power MOSFET. As in FIG. 23, this horizontal axis actually indicates the opening width of the opening OP of the hard mask HM (see FIG. 10). As shown in the graph of FIG. 13, in the present embodiment, there is a region (enclosed by a dashed line) where the breakdown voltage remains almost constant even if the column width (horizontal axis) changes, preventing fluctuations in breakdown voltage even if variations in column width occur.

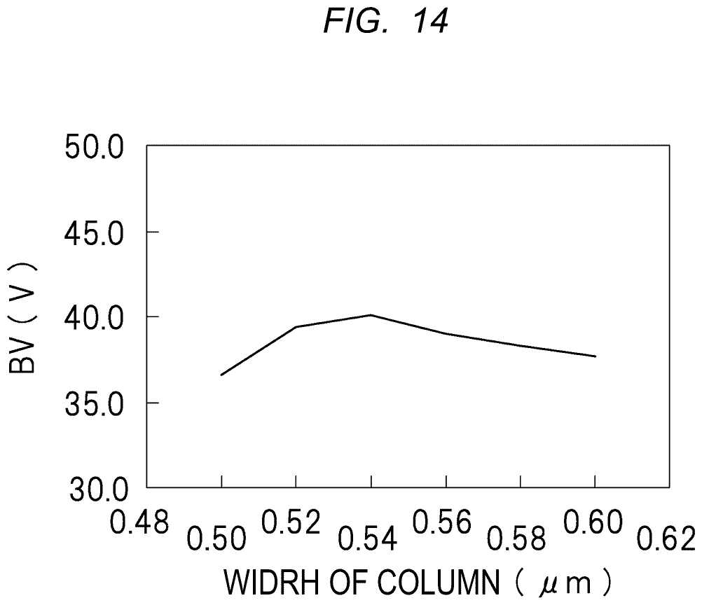

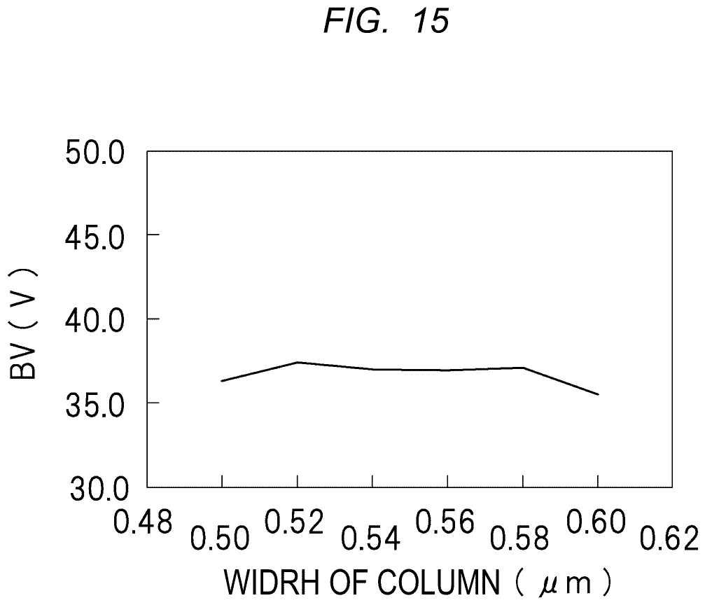

Furthermore, FIGS. 14 and 15 each show a graph of the relationship between the column width and breakdown voltage obtained from experiments conducted by the inventors using the semiconductor device of the present embodiment. The values on the vertical axis of each of FIGS. 14 and 15 are the same as the values on the vertical axis of the graph in FIG. 25 of the Comparative Example 2. Also, the value of one scale on the horizontal axis of FIGS. 14 and 15 is the same as the value of one scale on the horizontal axis of the graph in FIG. 25 of the Comparative Example 2.

Comparing the graph of FIG. 14 with the graph of the Comparative Example 2 in FIG. 25, the graph of the present embodiment in FIG. 14 is flatter, indicating that the breakdown voltage is stable in column against variations width. Furthermore, the graph of FIG. 15, which is another experimental example of the present embodiment, is even flatter compared to the graph of FIG. 14, indicating that it is easier to stabilize the breakdown voltage.

Therefore, in the semiconductor device of the present embodiment, the variation in breakdown voltage can be improved compared to Comparative Examples 1, 2, and 3. In other words, from the perspective of meeting both side standards, the reliability of the semiconductor device can be enhanced. Additionally, by improving the variation in breakdown voltage, the product robustness can be increased. Thus, even if there is a tendency for variation in the width of the P column, the decrease in yield due to variations in product breakdown voltage characteristics can be suppressed.

### First Modified Example

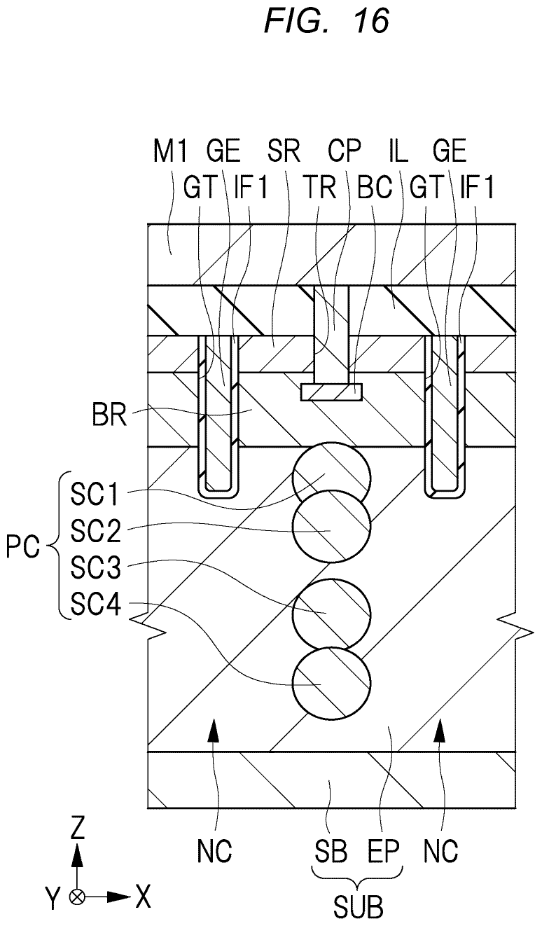

FIG. 16 shows a cross-sectional view of the semiconductor device according to the first modified example of the present embodiment. Here, among the plurality of column regions, a sub-column region SC4 is further formed on the bottom surface side of the laminated semiconductor substrate SUB, positioned from the third sub-column region SC3 from the main surface side of the laminated semiconductor substrate SUB. The sub-column region SC4, like the sub-column regions SC1, SC2 and SC3, is the p-type semiconductor region formed by the multi-stage ion-implantation process described using FIG. 10. The sub-column regions SC1, SC2, SC3, and SC4, aligned in the Z direction, constitute one p-type column region PC. In other words, each of the plurality of p-type column regions PC has the sub-column region SC4 at a position farthest from the main surface of the epitaxial layer EP.

A maximum impurity concentration of the sub-column region SC4 is equivalent to the maximum impurity concentration of the sub-column region SC3. A distance between the depth of the maximum impurity concentration position of the sub-column region SC3 and that of the sub-column region SC4 is, for example, equivalent to a bisected distance between the depth D1 of the maximum impurity concentration position of the sub-column region SC1 and the depth D3 of the maximum impurity concentration position of the sub-column region SC3.

According to this modified example, as explained using FIGS. 1 to 15, the variation in breakdown voltage can be improved, and the reliability of the semiconductor device can be enhanced. Furthermore, by increasing a number of sub-column regions constituting the p-type column region, the breakdown voltage of the vertical power MOSFET can be further enhanced.

### Second Modified Example

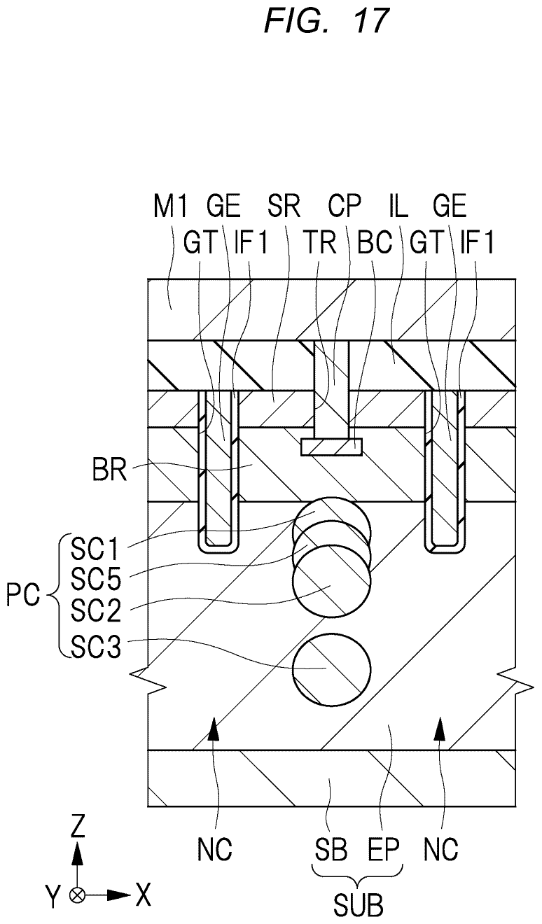

FIG. 17 shows a cross-sectional view of the semiconductor device according to the second modified example of the present embodiment. Here, among the plurality of column regions, a sub-column region SC5 is further formed between the sub-column regions SC1 and SC2. The sub-column region SC5, like the sub-column regions SC1, SC2 and SC3, is the p-type semiconductor region formed by the multi-stage ion-implantation process described using FIG. 10. The sub-column regions SC1, SC2, SC3 and SC5, aligned in the Z direction, constitute one p-type column region PC.

The impurity concentration in the region where sub-column regions SC1, SC2 and SC5 overlap is higher than the maximum impurity concentration of the sub-column region SC3. A maximum impurity concentration position of the sub-column region SC5 is, for example, located between the depth D1 of the maximum impurity concentration position of the sub-column region SC1 and the depth D2 of the maximum impurity concentration position of the sub-column region SC2.

According to this modified example, as explained using FIGS. 1 to 15, the variation in breakdown voltage can be improved, and the reliability of the semiconductor device can be enhanced. Additionally, by forming the sub-column region SC5, the breakdown voltage of the vertical power MOSFET can be stabilized further, and the occurrence of breakdown voltage variation can be suppressed.

### Third Modified Example

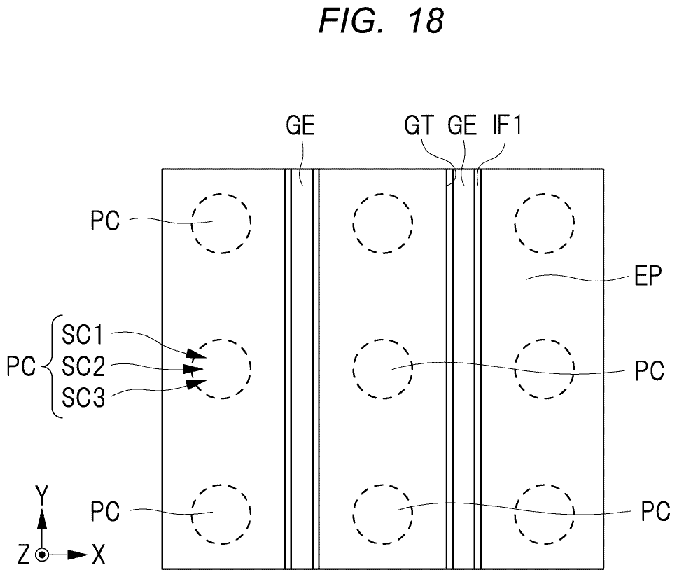

FIG. 18 shows the planar layout of the semiconductor device according to the third modified example of the present embodiment. As shown in FIG. 18, each of the plurality of p-type column regions PC may be arranged in a matrix in the X and Y directions.

### Fourth Modified Example

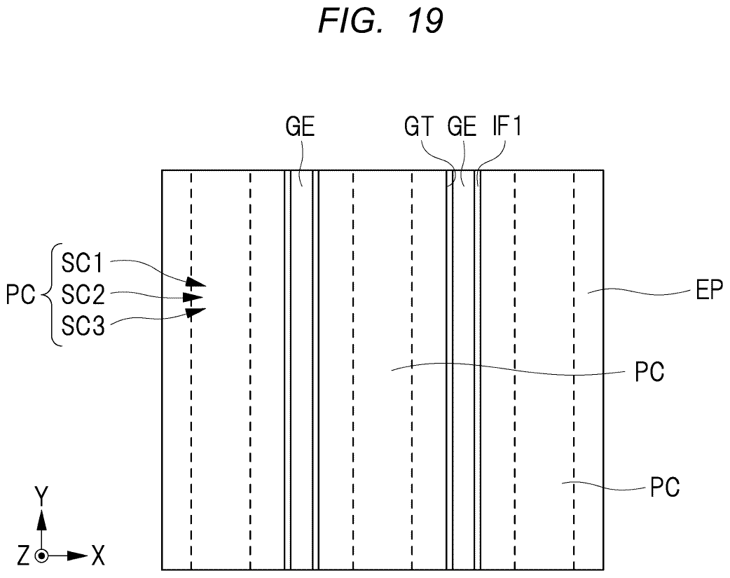

FIG. 19 shows the planar layout of the semiconductor device according to the fourth modified example of the present embodiment. As shown in FIG. 19, each of the plurality of p-type column regions PC may extend in the Y direction and be arranged in the X direction. Here, the plurality of p-type column regions PC and the epitaxial layer EP (drift region) separated by the plurality of p-type column regions PC are arranged in parallel at a predetermined interval.

Although the invention made by the present inventors has been specifically described based on the embodiment, the present invention is not limited to the described embodiment, and it is needless to say that various modifications can be made without departing from the gist thereof.

In the above embodiment, the semiconductor device comprising the substrate and the epitaxial layer made of Si (silicon) has been described, but a semiconductor device using SiC (silicon carbide) as the material instead of Si may also be used. That is, the semiconductor substrate may be composed of SiC.

In the above embodiment, the formation of an n-channel type MOSFET has been described, but the MOSFET may also be of the p-channel type. In the case of forming a p-channel type MOSFET, each semiconductor region constituting the above-described semiconductor device may be formed with the opposite conductivity type.

In addition, some of the contents described in the embodiment are listed below.

### Appendix 1

A method of manufacturing a semiconductor device, comprising the steps of:
(a) forming a semiconductor layer of a first conductivity type on a semiconductor substrate by epitaxial growth method,
(b) forming a trench reaching an intermediate depth of the semiconductor layer from a main surface of the semiconductor layer,
(c) forming a gate electrode in the trench via a gate insulating film,
(d) forming a semiconductor region of a second conductivity type opposite to the first conductivity type, in the semiconductor layer, adjacent to a side surface of the trench and shallower than a bottom of the trench,
(e) forming a plurality of column regions of the second conductivity type in the semiconductor layer so as to align in a first direction perpendicular to the main surface by using a protective film with an opening formed on the semiconductor layer as a mask and performing multiple ion implantations by gradually changing an implantation energy, wherein
the plurality of column regions includes, a first sub-column region, a second sub-column region and a third sub-column region, in order from a side closer to the main surface,
a distance between a position where an impurity concentration of the first sub-column region is maximum and a position where an impurity concentration of the second sub-column region is maximum is shorter than a distance between the position where the impurity concentration of the second sub-column region is maximum and a position where an impurity concentration of the third sub-column region is maximum,
and the position where the impurity concentration of the first sub-column region is maximum is located closer to the main surface than a bottom surface of the gate electrode.

### Appendix 2

The method of manufacturing the semiconductor device according to Appendix 1, wherein
an impurity concentration in a region where the first sub-column region and the second sub-column region are overlapped is higher than the maximum impurity concentration of the third sub-column region.

### Appendix 3

The method of manufacturing the semiconductor device according to Appendix 2, wherein
the impurity concentration in the region where the first sub-column region and the second sub-column region are overlapped is twice or more and five times or less than the maximum impurity concentration of the third sub-column region.

### Appendix 4

The method of manufacturing the semiconductor device according to Appendix 1, wherein
a width in the first direction of a first impurity region formed integrally with the first sub-column region and the second sub-column region is greater than a width in the first direction of the third sub-column region.

### Appendix 5

The method of manufacturing the semiconductor device according to Appendix 1, wherein
the distance between the position where the impurity concentration of the first sub-column region is maximum and the position where the impurity concentration of the second sub-column region is maximum is 0.3 micrometers or more and 0.6 micrometers or less, and
the distance between the position where the impurity concentration of the second sub-column region is maximum and the position where the impurity concentration of the third sub-column region is maximum is 0.6 micrometers or more and 1.0 micrometers or less.

### Appendix 6

The method of manufacturing the semiconductor device according to Appendix 4, wherein
the width in the first direction of the first impurity region is 0.5 micrometers or more and 1.0 micrometers or less, and
the width in the first direction of the third sub-column region is 0.2 micrometers or more and 0.5 micrometers or less.

### Appendix 7

The method of manufacturing the semiconductor device according to Appendix 1, wherein
a distance in the first direction between the main surface and the bottom surface of the gate electrode is 0.8 micrometers or more and 1.0 micrometers or less, and
a distance in the first direction between the main surface and the position where the impurity concentration of the first sub-column region is maximum is 0.7 micrometers or more and 0.9 micrometers or less.

### Appendix 8

The method of manufacturing the semiconductor device according to Appendix 1, wherein
widths in a second direction perpendicular to the first direction of the first sub-column region, the second sub-column region, and the third sub-column region are substantially the same respectively.

### Appendix 9

The method of manufacturing the semiconductor device according to Appendix 1, wherein
widths in a second direction perpendicular to the first direction of the first sub-column region, the second sub-column region, and the third sub-column region are 0.52 micrometers or more and 0.58 micrometers or less respectively.

### Appendix 10

The method of manufacturing the semiconductor device according to Appendix 1, wherein
the plurality of column regions further includes a fourth sub-column region at a position farthest from the main surface, and
a maximum impurity concentration of the fourth sub-column region is equivalent to the maximum impurity concentration of the third sub-column region.

### Appendix 11

The method of manufacturing the semiconductor device according to Appendix 1, wherein
the plurality of column regions further includes a fifth sub-column region at a position between the first sub-column region and the second sub-column region, and
an impurity concentration in a region where the first sub-column region, the second sub-column region and the fifth sub-column region are overlapped is higher than the maximum impurity concentration of the third sub-column region.

### Appendix 12

The method of manufacturing the semiconductor device according to Appendix 1, wherein
a super-junction structure is formed by the plurality of column regions and the semiconductor layer adjacent to the plurality of column regions.

What is claimed is:

1. A semiconductor device comprising:
a semiconductor substrate;
a drift region of a first conductivity type formed on the semiconductor substrate and having a main surface;
a plurality of column regions of a second conductivity type, opposite to the first conductivity type, formed in the drift region and spaced apart from each other in plan view; and
a gate electrode formed between each of the plurality of column regions, wherein
the plurality of column regions aligned in a first direction perpendicular to the main surface includes a first sub-column region, a second sub-column region and a third sub-column region, in order from a side closer to the main surface,
a distance between a position where an impurity concentration of the first sub-column region is maximum and a position where an impurity concentration of the second sub-column region is maximum is shorter than a distance between the position where the impurity concentration of the second sub-column region is maximum and a position where an impurity concentration of the third sub-column region is maximum,
and the position where the impurity concentration of the first sub-column region is maximum is located closer to the main surface than a bottom surface of the gate electrode.

2. The semiconductor device according to claim 1, wherein
an impurity concentration in a region where the first sub-column region and the second sub-column region are overlapped is higher than the maximum impurity concentration of the third sub-column region.

3. The semiconductor device according to claim 2, wherein
the impurity concentration in the region where the first sub-column region and the second sub-column region are overlapped is twice or more and five times or less than the maximum impurity concentration of the third sub-column region.

4. The semiconductor device according to claim 1, wherein
a width in the first direction of a first impurity region formed integrally with the first sub-column region and the second sub-column region is greater than a width in the first direction of the third sub-column region.

5. The semiconductor device according to claim 1, wherein
the distance between the position where the impurity concentration of the first sub-column region is maximum and the position where the impurity concentration of the second sub-column region is maximum is 0.3 micrometers or more and 0.6 micrometers or less, and
the distance between the position where the impurity concentration of the second sub-column region is maximum and the position where the impurity concentration of the third sub-column region is maximum is 0.6 micrometers or more and 1.0 micrometers or less.

6. The semiconductor device according to claim 4, wherein
the width in the first direction of the first impurity region is 0.5 micrometers or more and 1.0 micrometers or less, and
the width in the first direction of the third sub-column region is 0.2 micrometers or more and 0.5 micrometers or less.

7. The semiconductor device according to claim 1, wherein
a distance in the first direction between the main surface and the bottom surface of the gate electrode is 0.8 micrometers or more and 1.0 micrometers or less, and
a distance in the first direction between the main surface and the position where the impurity concentration of the first sub-column region is maximum is 0.7 micrometers or more and 0.9 micrometers or less.

8. The semiconductor device according to claim 1, wherein
widths in a second direction perpendicular to the first direction of the first sub-column region, the second sub-column region, and the third sub-column region are substantially the same respectively.

9. The semiconductor device according to claim 1, wherein
widths in a second direction perpendicular to the first direction of the first sub-column region, the second sub-column region, and the third sub-column region are 0.52 micrometers or more and 0.58 micrometers or less respectively.

10. The semiconductor device according to claim 1, wherein
the plurality of column regions further includes a fourth sub-column region at a position farthest from the main surface, and
a maximum impurity concentration of the fourth sub-column region is equivalent to the maximum impurity concentration of the third sub-column region.

11. The semiconductor device according to claim 1, wherein
the plurality of column regions further includes a fifth sub-column region at a position between the first sub-column region and the second sub-column region, and
an impurity concentration in a region where the first sub-column region, the second sub-column region and the fifth sub-column region are overlapped is higher than the maximum impurity concentration of the third sub-column region.

12. The semiconductor device according to claim 1, wherein
the plurality of column regions and the drift region separated by the plurality of column regions are arranged in parallel and spaced apart at a predetermined interval in plan view.

13. The semiconductor device according to claim 1, wherein
the plurality of column regions are arranged in a staggered manner in plan view.

14. The semiconductor device according to claim 1, wherein
a super-junction structure is formed by the plurality of column regions and the drift region adjacent to the plurality of column regions.

15. The semiconductor device according to claim 1, further comprising:
a semiconductor region of the second conductivity type formed on the drift region;
a source region of the first conductivity type formed on the semiconductor region;
an interlayer insulating film formed on the source region; and
a contact plug penetrating through the interlayer insulating film and the source region at a position overlapping the plurality of column regions and reaching the semiconductor region in plan view, wherein
the gate electrode is formed to penetrate the source region and the semiconductor region and reach the drift region.
